(19) United States
(12) Patent Application Publication
(10) Pub. No.: US 2013/0284230 A1
(43) Pub. Date: Oct. 31, 2013

(54) SOLAR CELL MODULE, ELECTRONIC DEVICE HAVING THE SAME, AND MANUFACTURING METHOD FOR SOLAR CELL

(71) Applicant: AU OPTRONICS CORPORATION, HSIN-CHU (TW)

(72) Inventors: Chun-Hao TU, HSIN-CHU (TW); Kuo-Sen KUNG, HSIN-CHU (TW); Ren-Hong JHAN, HSIN-CHU (TW); Ya-Zhi HSIAO, HSIN-CHU (TW); Ting-Chun LIN, HSIN-CHU (TW); Wei-Cheng WU, HSIN-CHU (TW); Jen-Pei TSENG, HSIN-CHU (TW); Jiun-Jye CHANG, HSIN-CHU (TW)

(73) Assignee: AU Optronics Corporation, HSIN-CHU (TW)

(21) Appl. No.: 13/707,731

(22) Filed: Dec. 7, 2012

(30) Foreign Application Priority Data
Apr. 27, 2012 (CN) 201210129658.3

(51) Int. Cl. G09G 5/00; H01L 31/18; H01L 31/05

(52) U.S. Cl. CPC G09G 5/00; H01L 31/0504; H01L 31/18; G09G 2330/02
USPC 136/244; 438/98; 345/211

(57) ABSTRACT

A solar cell module is provided and includes a first solar cell and a second solar cell. The first solar cell includes a first metal substrate, a first photoelectric conversion layer, a first top electrode layer, a first P-N junction semiconductor, and a first bottom electrode layer. The second solar cell includes a second metal substrate, a second photoelectric conversion layer, a second top electrode layer, a second P-N junction semiconductor, and a second bottom electrode layer. The first photoelectric conversion layer and the first P-N junction semiconductor are respectively located on two opposite sides of the first metal substrate. The second photoelectric conversion layer and the second P-N junction semiconductor are respectively located on two opposite sides of the second metal substrate. The second bottom electrode layer is located on the second P-N junction semiconductor, and is electrically coupled to the first metal substrate.

### RELATED APPLICATIONS

This application claims priority to China Application Serial Number 201210129658.3, filed Apr. 27, 2012, which is herein incorporated by reference.

### BACKGROUND

1. Technical Field

The present disclosure relates to a solar cell module, and more particularly to a solar cell module including bypass diode.

2. Description of Related Art

Recently, solar cell modules have been extensively used in portable electronic devices, as well as on roofs and external walls of buildings. A solar cell module usually includes a plurality of solar cells. When one of the solar cells in the solar cell module is shaded, the power may not be normally outputted due to shadow effect. Moreover, the shaded solar cell may generate high temperature to damage the solar cell module. A conventional method for solving shadow effect of the solar cell module is to assemble a diode adjacent to each of the solar cells. When one of the solar cells cannot normally provide power, another electric current pass through the diode is provided, such that the solar cell module can be uninterruptedly working without damage.

FIG. 1 is a schematic view of a conventional solar cell module 100 not being shaded. The solar cell module 100 includes a plurality of solar cells 110 and a plurality of diodes 130. A plurality of ribbons 120 are electrically coupled to the solar cell module 100, and the diodes 130 are respectively connected in parallel to the solar cells 110 by the ribbons 120. When the solar cell module 100 is radiated by the sun 140, an electric current I1 can flow along the ribbons 120 because the solar cell module 100 is not be shaded.

FIG. 2 is a schematic view of the conventional solar cell module 100 shown in FIG. 1 when a portion of which is shaded. When one of the solar cells 110 is shaded by a dark cloud, the shaded solar cell 110 cannot provide power normally. At this moment, an electric current I2 can pass through the diode 130 corresponding to the shaded solar cells 110 by a conductive wire 132, but not through the shaded solar cells 110, such that the solar cell module 100 can be uninterruptedly working without damage.

### SUMMARY

An aspect of the present disclosure is to provide a solar cell module.

In an embodiment of the present disclosure, a solar cell module includes a first solar cell and a second solar cell. The first solar cell includes a first metal substrate having a first surface and a second surface opposite to the first surface, a first photoelectric conversion layer located on a side the same as the first surface of the first metal substrate, a first top electrode layer located on a side of the first photoelectric conversion layer opposite to the first metal substrate, a first P-N junction semiconductor located on a side the same as the second surface of the first metal substrate, and a first bottom electrode layer located on a side of the first P-N junction semiconductor opposite to the first metal substrate. The second solar cell includes a second metal substrate having a first surface and a second surface opposite to the first surface, a second photoelectric conversion layer located on a side the same as the first surface of the second metal substrate, a second top electrode layer located on a side of the second photoelectric conversion layer opposite to the second metal substrate and electrically coupled to the first metal substrate, a second P-N junction semiconductor located on a side the same as the second surface of the second metal substrate, and a second bottom electrode layer located on a side of the second P-N junction semiconductor opposite to the second metal substrate and electrically coupled to the first metal substrate.

An aspect of the present disclosure is to provide an electronic device.

In an embodiment of the present disclosure, an electronic device includes a display screen for displaying an image, an input receiving unit for receiving an input instruction, a control unit electrically coupled to the display screen and the input receiving unit for controlling the display screen to display the corresponding image in accordance with the input instruction received by the input receiving unit, and the solar cell module electrically coupled to the display screen, the input receiving unit, and the control unit for providing power to the display screen, the input receiving unit, and the control unit.

An aspect of the present disclosure is to provide a manufacturing method for solar cell.

In an embodiment of the present disclosure, a manufacturing method for solar cell includes the steps of:

A first metal substrate having a first surface and a second surface opposite to the first surface is provided.

A first P-type semiconductor layer is deposited or coated on the first surface.

A first I-type semiconductor layer is deposited or coated on the first P-type semiconductor layer.

A first N-type semiconductor layer is deposited or coated on the first I-type semiconductor layer.

A first top electrode layer is formed on the first N-type semiconductor layer.

A second N-type semiconductor layer is deposited or coated on the second surface.

A second P-type semiconductor layer is deposited or coated on the second N-type semiconductor layer.

A first bottom electrode layer is formed on the second P-type semiconductor layer.

An aspect of the present disclosure is to provide a manufacturing method for solar cell.

In an embodiment of the present disclosure, a manufacturing method for solar cell includes the steps of:

A first metal substrate having a first surface and a second surface opposite to the first surface is provided.

A first N-type semiconductor layer is deposited or coated on the first surface.

A first I-type semiconductor layer is deposited or coated on the first N-type semiconductor layer.

A first P-type semiconductor layer is deposited or coated on the first I-type semiconductor layer.

A first top electrode layer is formed on the first P-type semiconductor layer.

A second P-type semiconductor layer is deposited or coated on the second surface.

A second N-type semiconductor layer is deposited or coated on the second P-type semiconductor layer.

A first bottom electrode layer is formed on the second N-type semiconductor layer.

### BRIEF DESCRIPTION OF THE DRAWINGS

FIG. 1 is a schematic view of a conventional solar cell module not being shaded;

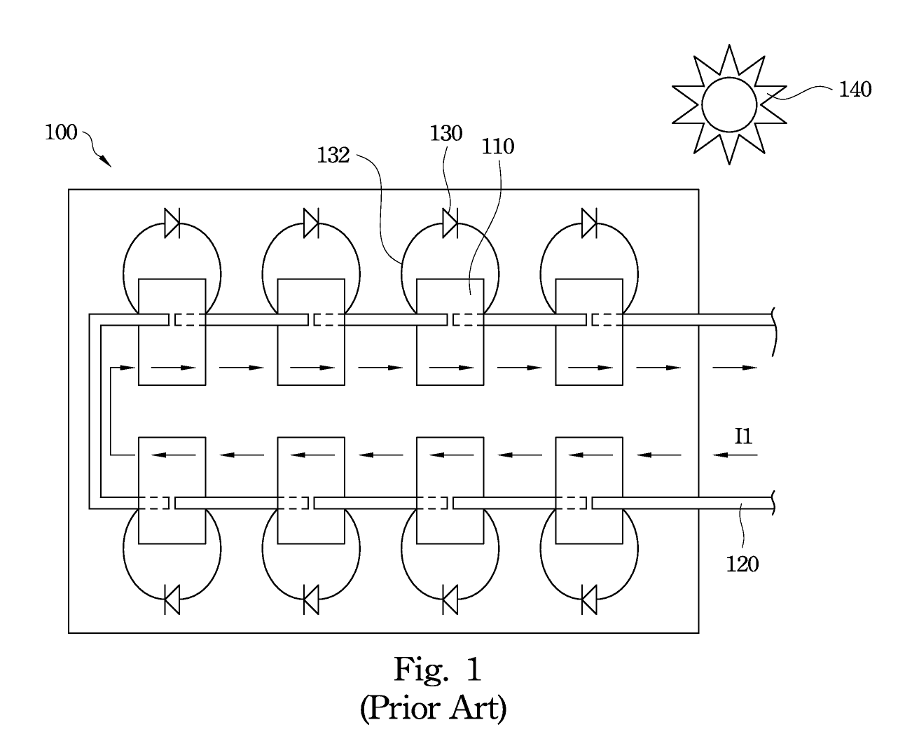

FIG. 2 is a schematic view of the conventional solar cell module shown in FIG. 1 when a portion of which is shaded;

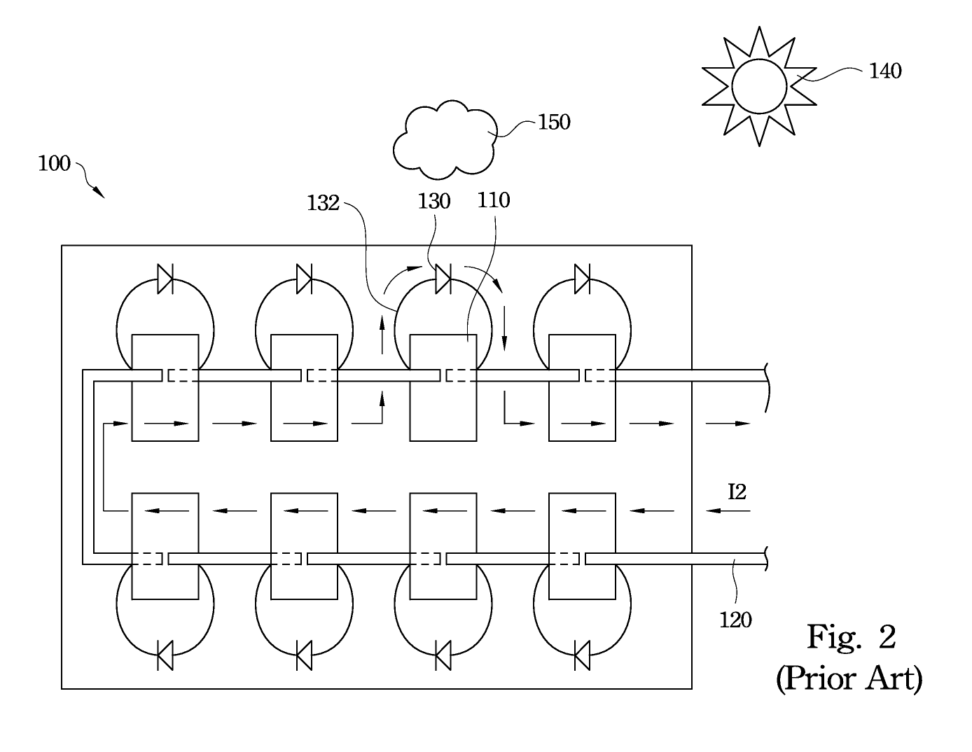

FIG. 3 is a top view of a solar cell module of an embodiment of the present disclosure;

FIG. 4 is a cross sectional view of the solar cell module taken along line 4-4′ shown in FIG. 3;

FIG. 5 is a schematic view of the solar cell module not shaded shown in FIG. 4.

FIG. 6 is a schematic view of the solar cell module shown in FIG. 5 when a portion of which is shaded;

FIG. 7 is a schematic view of a diode equivalent circuit of the solar cell module shown in FIG. 4;

FIG. 8 is a cross sectional view of a solar cell module of an embodiment of the present disclosure;

FIG. 9 is a schematic view of the solar cell module shown in FIG. 8 when a portion of which is shaded;

FIG. 10 is a block diagram of an electric device of an embodiment of the present disclosure;

FIG. 11 is a flow diagram of a manufacturing method for solar cell of an embodiment of the present disclosure; and

FIG. 12 is a flow diagram of a manufacturing method for solar cell of an embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

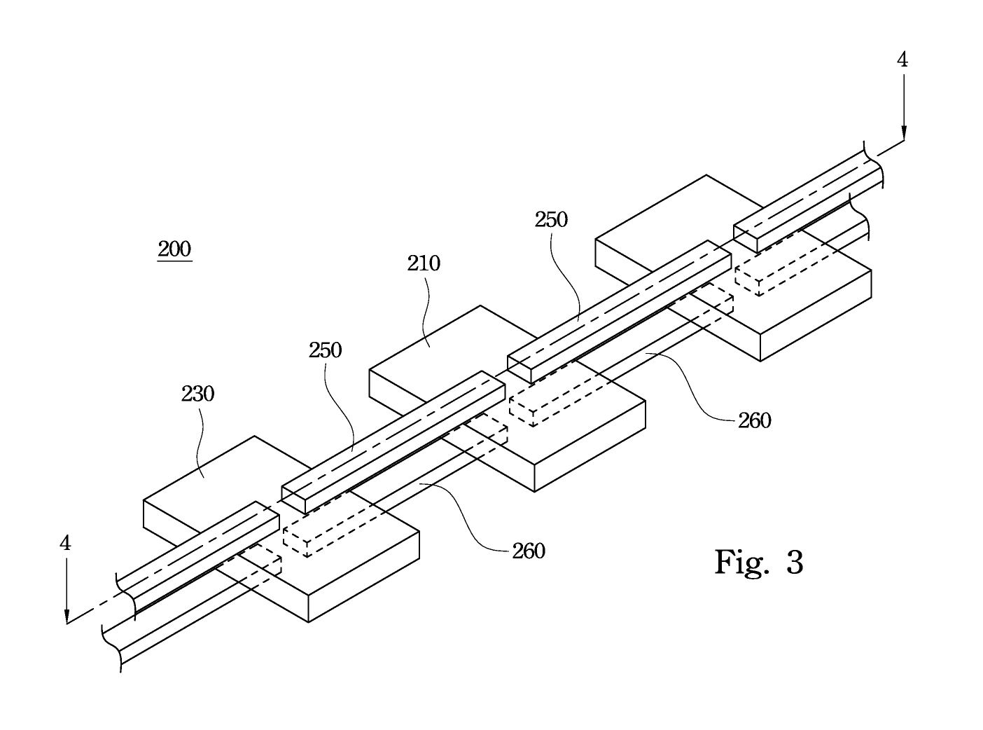

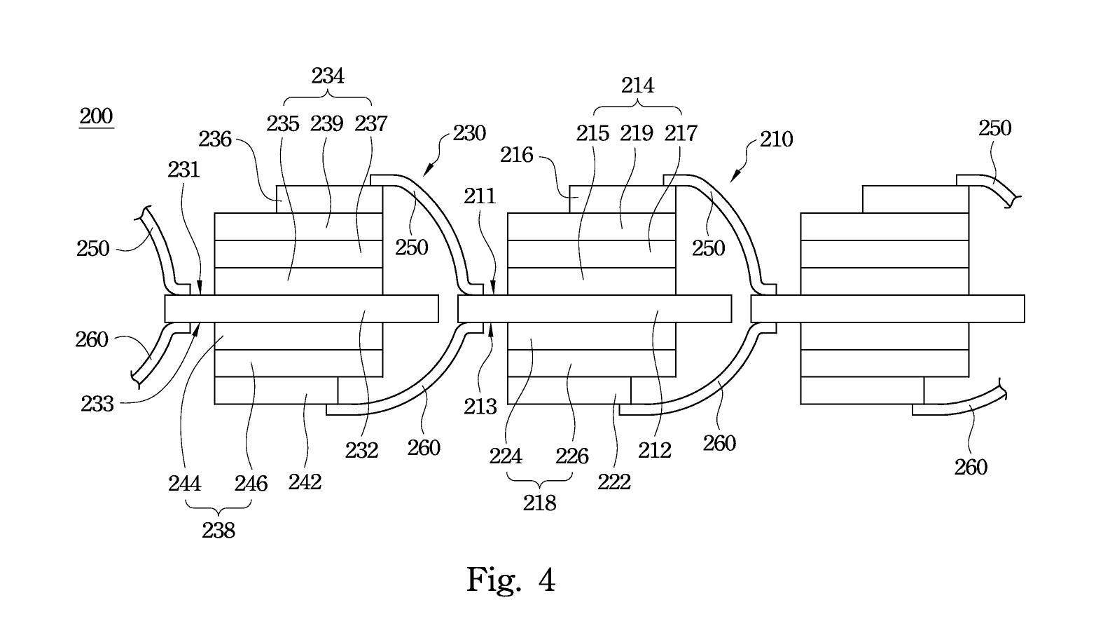

FIG. 3 is a top view of a solar cell module 200 of an embodiment of the present disclosure. FIG. 4 is a cross sectional view of the solar cell module 200 taken along line 4-4′ shown in FIG. 3. As shown in FIG. 3 and FIG. 4, the solar cell module 200 includes a first solar cell 210 and a second solar cell 230. The first solar cell 210 includes a first metal substrate 212, first photoelectric conversion layer 214, a first top electrode layer 216, a first P-N junction semiconductor 218, and a first bottom electrode layer 222. The second solar cell 230 includes a second metal substrate 232, a second photoelectric conversion layer 234, a second top electrode layer 236, a second P-N junction semiconductor 238, and a second bottom electrode layer 242.

The first metal substrate 212 has a first surface 211 and a second surface 213 opposite to the first surface 211. The first photoelectric conversion layer 214 is located on a side the same as the first surface 211 of the first metal substrate 212. The first top electrode layer 216 is located on the first photoelectric conversion layer 214. The first P-N junction semiconductor 218 is located on a side the same as the second surface 213 of the first metal substrate 212. The first bottom electrode layer 222 is located on the first P-N junction semiconductor 218. That is to say, the first top electrode layer 216 is located on a side of the first photoelectric conversion layer 214 opposite to the first metal substrate 212, and the first bottom electrode layer 222 is located on a side of the first P-N junction semiconductor 218 opposite to the first metal substrate 212.

Similarly, the second metal substrate 232 has a first surface 231 and a second surface 233 opposite to the first surface 231. The second photoelectric conversion layer 234 is located on a side the same as the first surface 231 of the second metal substrate 232. The second top electrode layer 236 is located on the second photoelectric conversion layer 234. The second P-N junction semiconductor 238 is located on a side the same as the second surface 233 of the second metal substrate 232. The second bottom electrode layer 242 is located on the second P-N junction semiconductor 238. That is to say, the second top electrode layer 236 is located on a side of the second photoelectric conversion layer 234 opposite to the second metal substrate 232, and the second bottom electrode layer 242 is located on a side of the second P-N junction semiconductor 238 opposite to the second metal substrate 232.

In this embodiment, the first photoelectric conversion layer 214 is in ohmic contact with the first surface 211 of the first metal substrate 212, and the first P-N junction semiconductor 218 is in ohmic contact with the second surface 213 of the first metal substrate 212. Similarly, the second photoelectric conversion layer 234 is in ohmic contact with the first surface 231 of the second metal substrate 232, and the second P-N junction semiconductor 238 is in ohmic contact with the second surface 233 of the second metal substrate 232. The second top electrode layer 236 is electrically coupled to the first surface 211 of the first metal substrate 212 by a ribbon 250, and the second bottom electrode layer 242 is electrically coupled to the second surface 213 of the first metal substrate 212 by a ribbon 260.

Furthermore, the first photoelectric conversion layer 214 may include a first P-type semiconductor layer 215, and a first N-type semiconductor layer 219. The first photoelectric conversion layer 214 may further include a first I-type semiconductor layer 217. The first P-type semiconductor layer 215 is located on a side the same as the first surface 211 of the first metal substrate 212. In this embodiment, the first P-type semiconductor layer 215 is located on the first surface 211 of the first metal substrate 212. The first I-type semiconductor layer 217 is located on the first P-type semiconductor layer 215. The first N-type semiconductor layer 219 is located on the first I-type semiconductor layer 217. The first P-N junction semiconductor 218 may include a second N-type semiconductor layer 224 and a second P-type semiconductor layer 226. The second N-type semiconductor layer 224 is located on a side the same as the second surface 213 of the first metal substrate 212. The second P-type semiconductor layer 226 is located on the second N-type semiconductor layer 224, and is located between the second N-type semiconductor layer 224 and the first bottom electrode layer 222.

Similarly, the second photoelectric conversion layer 234 may include a third P-type semiconductor layer 235, and a third N-type semiconductor layer 239. The second photoelectric conversion layer 234 may further include a second I-type semiconductor layer 237. The third P-type semiconductor layer 235 is located on a side the same as the first surface 231 of the second metal substrate 232. In this embodiment, the third P-type semiconductor layer 235 is located on the first surface 231 of the second metal substrate 232. The second I-type semiconductor layer 237 is located on the third P-type semiconductor layer 235. The third N-type semiconductor layer 239 is located on the second I-type semiconductor layer 237. Moreover, the second P-N junction semiconductor 238 may include a fourth N-type semiconductor layer 244 and a fourth P-type semiconductor layer 246. The fourth N-type semiconductor layer 244 is located on a side the same as the second surface 233 of the second metal substrate 232. The fourth P-type semiconductor layer 246 is located on the fourth N-type semiconductor layer 244, and is located between the fourth N-type semiconductor layer 244 and the second bottom electrode layer 242.

However, in other embodiments, the positive and negative levels of the first photoelectric conversion layer 214, the first P-N junction semiconductor 218, the second photoelectric conversion layer 234, and the second P-N junction semiconductor 238 may be different form the solar cell module 200 shown FIG. 4. That is to say that the positions of the first P-type semiconductor layer 215 and the first N-type semiconductor layer 219 can be selectively exchanged, the positions of the second N-type semiconductor layer 224 and the second P-type semiconductor layer 226 can be selectively exchanged, the positions of the third P-type semiconductor layer 235 and the third N-type semiconductor layer 239 can be selectively exchanged, and the positions of the fourth N-type semiconductor layer 244 and the fourth P-type semiconductor layer 246 can be selectively exchanged. The present disclosure is not limited in this regard.

In this embodiment, the material of the first and second metal substrates 212, 232 may be selected from the group consisting of gold, silver, copper, iron, tin, indium, aluminum, and platinum. The material of the first top electrode layer 216, the first bottom electrode layer 222, the second top electrode layer 126, and the second bottom electrode layer 242 may include indium tin oxide, indium zinc oxide, aluminum tin oxide, aluminum zinc oxide, or indium germanium zinc oxide. The material of the first and second photoelectric conversion layers 214, 234 may include amorphous silicon, poly silicon, cadmium telluride, copper indium gallium selenium, gallium arsenide, or polymer. The material of the first and second P-N junction semiconductors 218, 238 may include amorphous silicon, poly silicon, cadmium telluride, copper indium gallium selenium, or gallium arsenide.

It is to be noted that the connection relationships of the aforementioned elements will not be repeated in the following description.

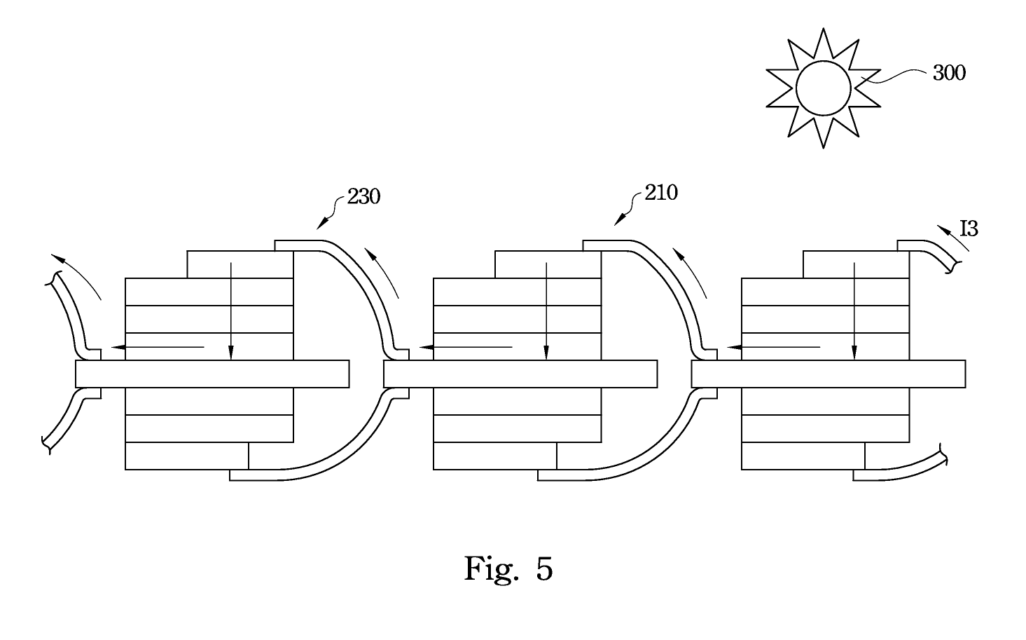

FIG. 5 is a schematic view of the solar cell module 200 not shaded shown in FIG. 4. As shown in FIG. 4 and FIG. 5, when the solar cell module 200 is exposed under the sun 300, the first solar cell 210 and the second solar cell 230 are not shaded. An electric current I3 can flow in the first top electrode layer 216, afterwards, the electric current I3 flows out the first metal substrate 212 through the first photoelectric conversion layers 214, and flows in the second top electrode layer 236. Next, the electric current I3 flows out the second metal substrate 232 through the second photoelectric conversion layer 234, and flows in another adjacent solar cell (not shown).

In this embodiment, the sun 300 is only an example as a light source, in other embodiments, the solar cell module 200 may be shined by another light source, such as various lighting devices having bulbs, fluorescent tubes, or light emitting diodes.

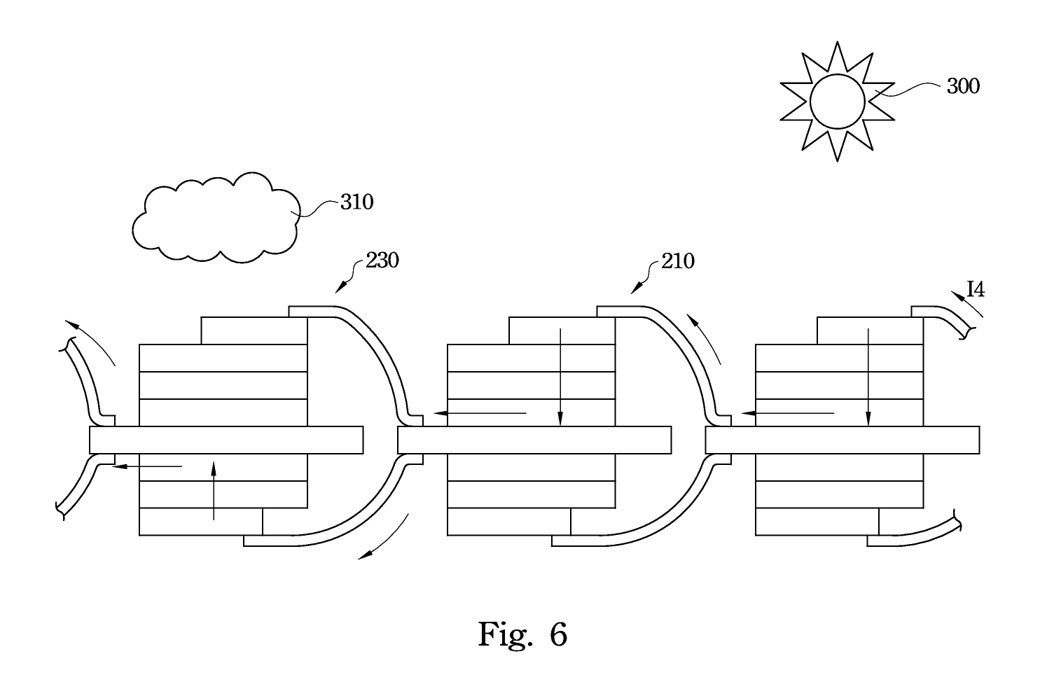

FIG. 6 is a schematic view of the solar cell module 200 shown in FIG. 5 when a portion of which is shaded. As shown in FIG. 4 and FIG. 6, when the solar cell module 200 is exposed under the sun 300, the first solar cell 210 is not shaded but the second solar cell 230 is shaded by a dark cloud 310. At this moment, an electric current I4 can flow in the first top electrode layer 216, afterwards, the electric current I4 flows out the first metal substrate 212 through the first photoelectric conversion layers 214, and flows in the second bottom electrode layer 242. Next, the electric current I4 flows out the second metal substrate 232 through the second P-N junction semiconductor 238, and flows in another adjacent solar cell (not shown).

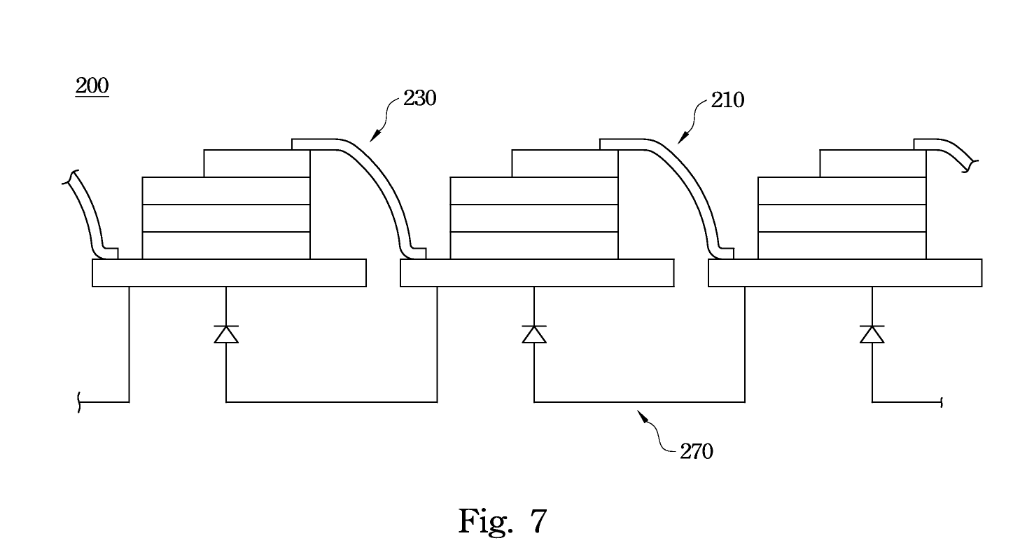

As a result, although the first and second solar cells 210, 230 of the solar cell module 200 is not electrically connected to a conventional diode, the solar cell module 200 has a diode equivalent circuit 270 (shown in FIG. 7) to prevent shadow effect so as not to output power, such that the solar cell module 200 can keep working and is not damaged. Moreover, the first P-N junction semiconductor 218 and the first bottom electrode layer 222 can be formed when the first solar cell 210 is manufactured, and the second P-N junction semiconductor 238 and the second bottom electrode layer 242 can be formed when the second solar cell 230 is manufactured. Therefore, the process difficulty of the solar cell module 200 is not increased, and the manufacturing and material costs of mounting the conventional diode and additional conductive wire adjacent to each solar cell in the past can be economized. Furthermore, the area of the solar cell module 200 is not affected by the conventional diode so as to have more useful area. As a result, the areas of the first and second solar cells 210, 230 may be increased, such that the power output of the solar cell module 200 can be improved. In addition, since the solar cell module 200 can decrease the depth and the area thereof, the solar cell module 200 is advantageous to be applied in an electric device.

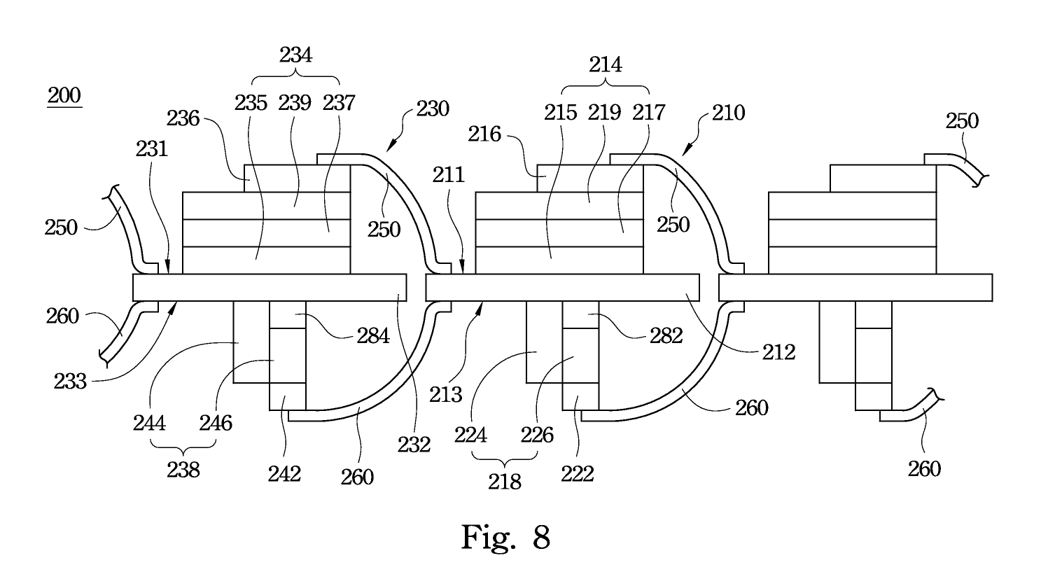

FIG. 8 is a cross sectional view of a solar cell module 200 of an embodiment of the present disclosure. As shown in FIG. 8, the solar cell module 200 includes the first and second solar cell 210, 230. The difference between this embodiment and the aforementioned embodiments is that the first P-N junction semiconductor 218 includes the second N-type semiconductor layer 224, a first insulator 282, and the second P-type semiconductor layer 226. The second N-type semiconductor layer 224 is located on a side the same as the second surface 213 of the first metal substrate 212. The first insulator 282 is located on a side the same as the second surface 213 of the first metal substrate 212, and is adjacent to the second N-type semiconductor layer 224. The second P-type semiconductor layer 226 is located on the first insulator 282, and is located between the first insulator 282 and the first bottom electrode layer 222.

Similarly, the second P-N junction semiconductor 238 includes the fourth N-type semiconductor layer 244, a second insulator 284, and the fourth P-type semiconductor layer 246. The fourth N-type semiconductor layer 244 is located on a side the same as the second surface 233 of the second metal substrate 232. The second insulator 284 is located on a side the same as the second surface 233 of the second metal substrate 232, and is adjacent to the fourth N-type semiconductor layer 244. The fourth P-type semiconductor layer 246 is located on the second insulator 284, and is located between the second insulator 284 and the second bottom electrode layer 242.

In this embodiment, since the material usage quantity (e.g., indium tin oxide) of the first and second bottom electrode layer 222, 242 can be decreased, the cost of the solar cell module 200 can be saved.

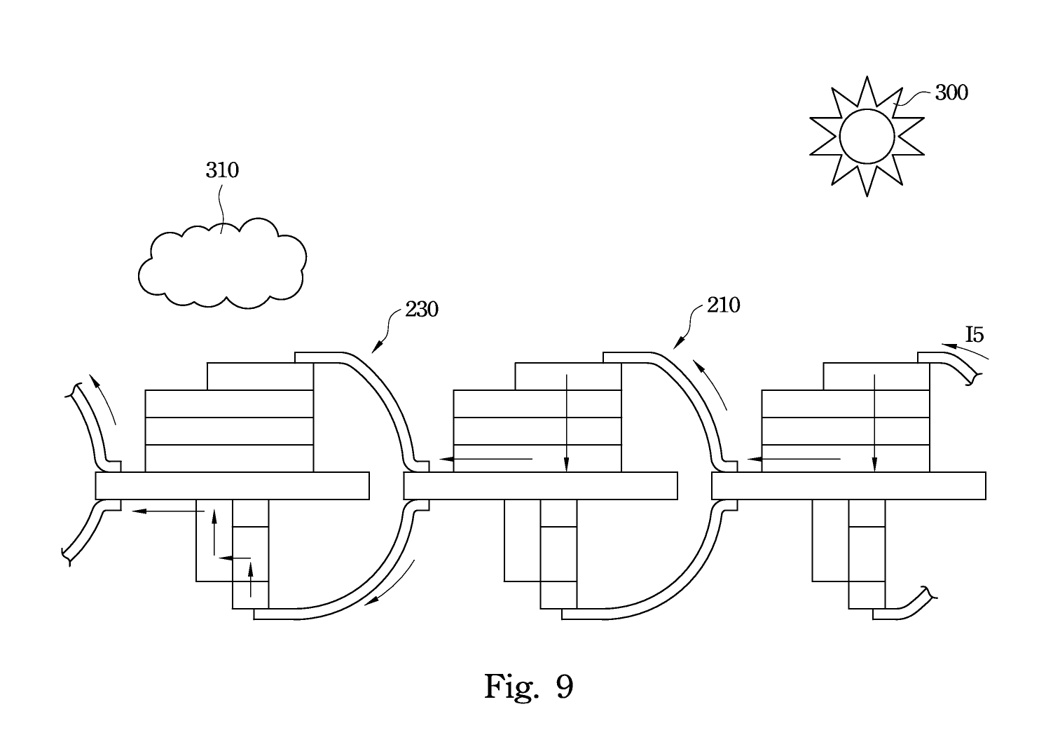

FIG. 9 is a schematic view of the solar cell module 200 shown in FIG. 8 when a portion of which is shaded. As shown in FIG. 8 and FIG. 9, when the solar cell module 200 is exposed under the sun 300, the first solar cell 210 is not shaded but the second solar cell 230 is shaded by the dark cloud 310. At this moment, an electric current I5 can flow in the first top electrode layer 216, afterwards, the electric current I5 flows out the first metal substrate 212 through the first photoelectric conversion layers 214, and flows in the second bottom electrode layer 242. Next, the electric current I5 flows out the second metal substrate 232 through the second P-N junction semiconductor 238, and flows in another adjacent solar cell (not shown).

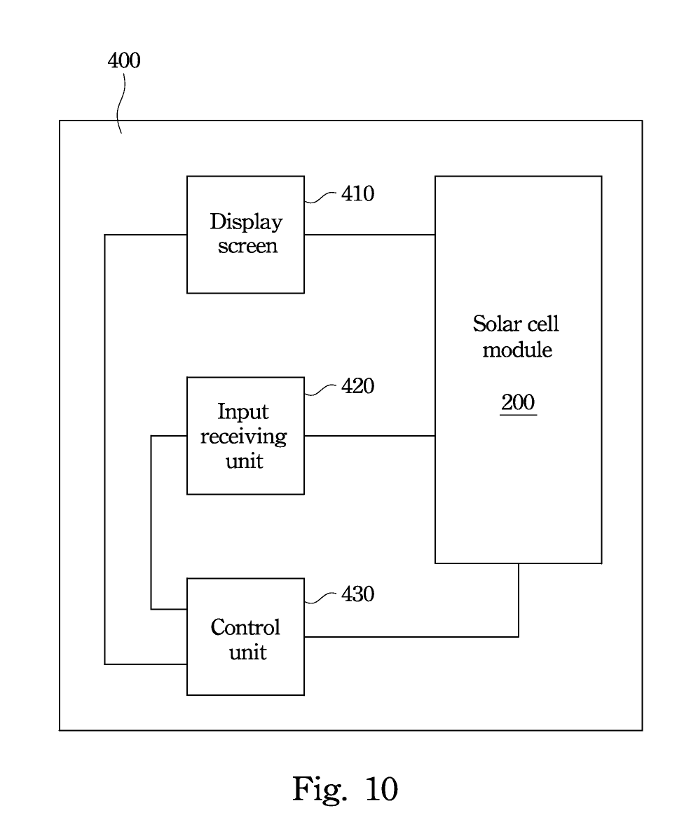

FIG. 10 is a block diagram of an electric device 400 of an embodiment of the present disclosure. As shown in FIG. 10, the electronic device 400 includes a display screen 410, an input receiving unit 420, a control unit 430, and the solar cell module 200. The display screen 410 can display an image. The input receiving unit 420 can receive an input instruction. The control unit 430 is electrically coupled to the display screen 410 and the input receiving unit 420. The control unit 430 controls the display screen 410 to display the corresponding image in accordance with the input instruction received by the input receiving unit 420. The solar cell module 200 is electrically coupled to the display screen 410, the input receiving unit 420, and the control unit 430 to provide power to the display screen 410, the input receiving unit 420, and the control unit 430. The control unit 430 may be an integrated circuit, a field-programmable gate array (FPGA), an application-specific integrated circuit (ASIC), or a microcontroller Unit (MCU). The display screen 410 may be a liquid crystal (LCD) display screen, an organic light emitting diode display screen, a reflective type display screen, a light emitting diode (LED) display screen, or a flexible electrophoretic display (EPD) screen. The input receiving unit 420 may be such as a camera, a keyboard, a button, a touch panel, a microphone, a mouse, a light sensor, or another sensor capable of receiving the input instruction or sensing external environmental variations.

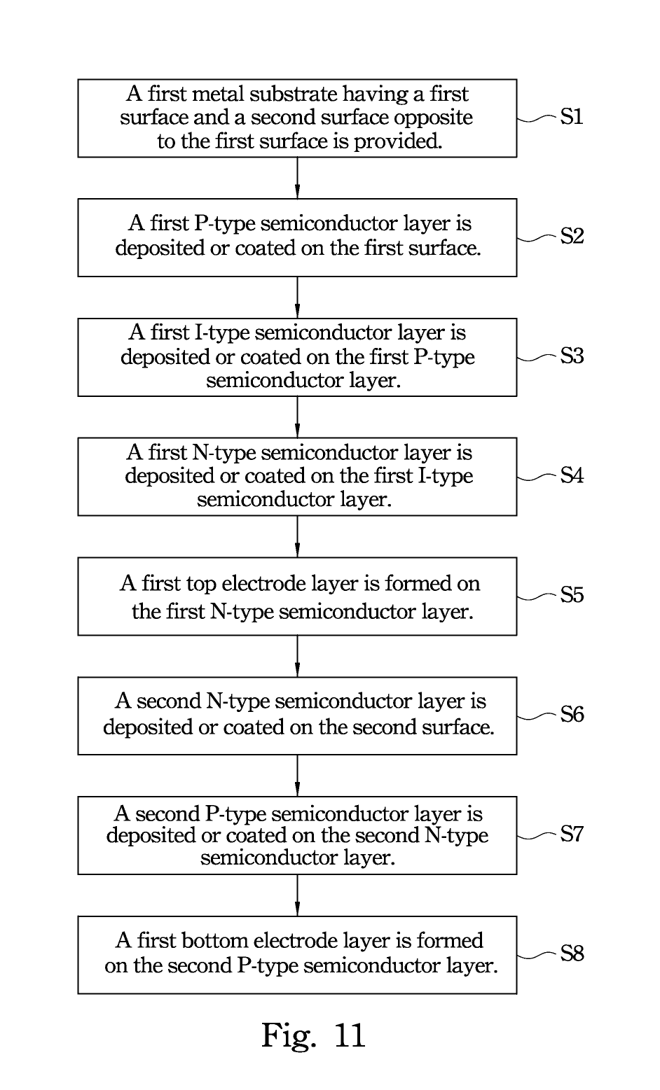

FIG. 11 is a flow diagram of a manufacturing method for solar cell of an embodiment of the present disclosure. In step S1, a first metal substrate having a first surface and a second surface opposite to the first surface is provided. In step S2, a first P-type semiconductor layer is deposited or coated on the first surface. In step S3, a first I-type semiconductor layer is deposited or coated on the first P-type semiconductor layer. In step S4, a first N-type semiconductor layer is deposited or coated on the first I-type semiconductor layer. In step S5, a first top electrode layer is formed on the first N-type semiconductor layer. In step S6, a second N-type semiconductor layer is deposited or coated on the second surface. In step S7, a second P-type semiconductor layer is deposited or coated on the second N-type semiconductor layer. In step S8, a first bottom electrode layer is formed on the second P-type semiconductor layer. In this embodiment, the light receiving surface of the solar cell is the N-type semiconductor layer.

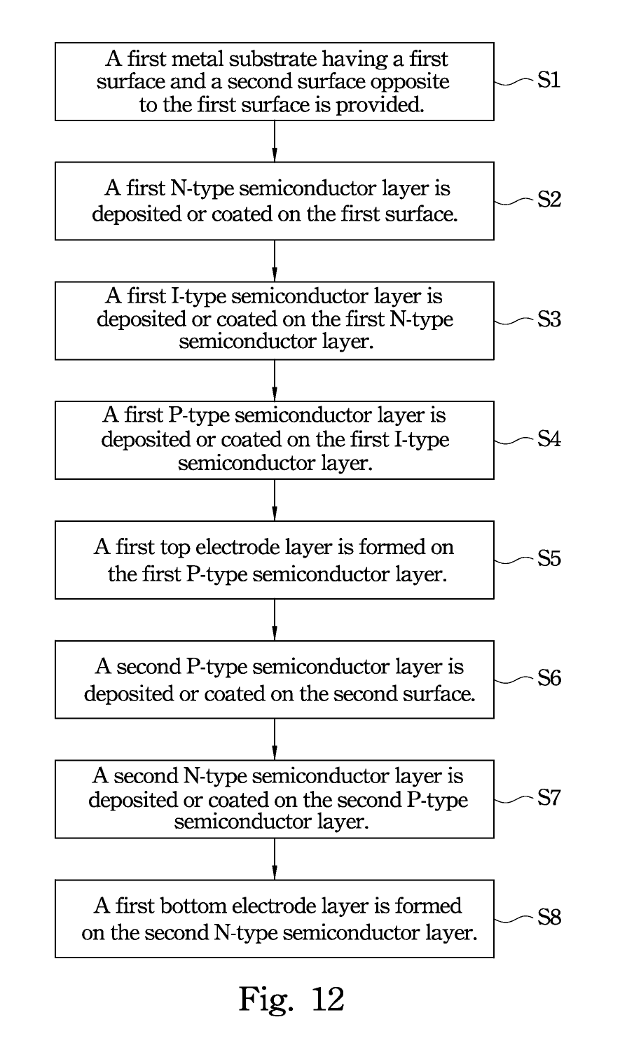

FIG. 12 is a flow diagram of a manufacturing method for solar cell of an embodiment of the present disclosure. In step S1, a first metal substrate having a first surface and a second surface opposite to the first surface is provided. In step S2, a first N-type semiconductor layer is deposited or coated on the first surface. In step S3, a first I-type semiconductor layer is deposited or coated on the first N-type semiconductor layer. In step S4, a first P-type semiconductor layer is deposited or coated on the first I-type semiconductor layer. In step S5, a first top electrode layer is formed on the first P-type semiconductor layer. In step S6, a second P-type semiconductor layer is deposited or coated on the second surface. In step S7, a second N-type semiconductor layer is deposited or coated on the second P-type semiconductor layer. In step S8, a first bottom electrode layer is formed on the second N-type semiconductor layer. In this embodiment, the light receiving surface of the solar cell is the P-type semiconductor layer.

In the aforementioned embodiments of the present disclosure, the second top electrode layer is located on the second photoelectric conversion layer and is electrically coupled to the first metal substrate. The second P-N junction semiconductor is located on the second surface of the second metal substrate. Moreover, the second bottom electrode layer is located on a side away from the second metal substrate of the second P-N junction semiconductor and is electrically coupled to the first metal substrate. When the solar cell module is used and the second solar cell is not shaded, an electric current flows in the second top electrode layer from the first metal substrate, and the electric current flows out the second substrate through the second photoelectric conversion layer. When the second solar cell is shaded, the electric current flows in the second bottom electrode layer from the first metal substrate, and the electric current flows out the second metal substrate through the second P-N junction semiconductor. As a result, although each of the solar cell of the solar cell module is not electrically connected to a conventional diode, the solar cell module has a diode equivalent circuit to prevent shadow effect so as not to output power, such that the solar cell module can keep working and is not damaged.

Moreover, the second P-N junction semiconductor and the second bottom electrode layer can be formed when the solar cell is manufactured. Therefore, the process difficulty of the solar cell module is not increased, and the manufacturing and material costs of mounting the conventional diode and additional conductive wire adjacent to the solar cell in the past can be economized. Furthermore, the area of the solar cell module is not affected by the conventional diode so as to have more useful area. As a result, the area of the solar cell is increased, such that the power output of the solar cell module is improved. In addition, since the solar cell module can decrease the depth and the area thereof, the solar cell module is advantageous to be applied in an electric device.

The reader's attention is directed to all papers and documents which are filed concurrently with this specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A solar cell module comprising:
a first solar cell comprising:
a first metal substrate having a first surface and a second surface opposite to the first surface;
a first photoelectric conversion layer located on a side the same as the first surface of the first metal substrate;
a first top electrode layer located on a side of the first photoelectric conversion layer opposite to the first metal substrate;
a first P-N junction semiconductor located on a side the same as the second surface of the first metal substrate; and
a first bottom electrode layer located on a side of the first P-N junction semiconductor opposite to the first metal substrate; and
a second solar cell comprising:
a second metal substrate having a first surface and a second surface opposite to the first surface;
a second photoelectric conversion layer located on a side the same as the first surface of the second metal substrate;
a second top electrode layer located on a side of the second photoelectric conversion layer opposite to the second metal substrate, and electrically coupled to the first metal substrate;
a second P-N junction semiconductor located on a side the same as the second surface of the second metal substrate; and
a second bottom electrode layer located on a side of the second P-N junction semiconductor opposite to the second metal substrate, and
electrically coupled to the first metal substrate.

2. The solar cell module as claimed in claim 1, wherein the first photoelectric conversion layer comprises:
a first P-type semiconductor layer located on the first surface of the first metal substrate;
a first I-type semiconductor layer located on the first P-type semiconductor layer; and
a first N-type semiconductor layer located on the first I-type semiconductor layer.

3. The solar cell module as claimed in claim 2, wherein the first P-N junction semiconductor comprises:
a second N-type semiconductor layer located on a side the same as the second surface of the first metal substrate; and
a second P-type semiconductor layer located on the second N-type semiconductor layer, and located between the second N-type semiconductor layer and the first bottom electrode layer.

4. The solar cell module as claimed in claim 3, wherein the second photoelectric conversion layer comprises:
a third P-type semiconductor layer located on a side the same as the first surface of the second metal substrate;
a second I-type semiconductor layer located on the third P-type semiconductor layer; and
a third N-type semiconductor layer located on the second I-type semiconductor layer.

5. The solar cell module as claimed in claim 4, wherein the second P-N junction semiconductor comprises:
a fourth N-type semiconductor layer located on a side the same as the second surface of the second metal substrate; and
a fourth P-type semiconductor layer located between the fourth N-type semiconductor layer and the second bottom electrode layer.

6. The solar cell module as claimed in claim 5, wherein the first photoelectric conversion layer is in ohmic contact with the first surface of the first metal substrate, and the first P-N junction semiconductor is in ohmic contact with the second surface of the first metal substrate;
the second photoelectric conversion layer is in ohmic contact with the first surface of the second metal substrate; and
the second P-N junction semiconductor is in ohmic contact with the second surface of the second metal substrate.

7. The solar cell module as claimed in claim 6, wherein the material of the first top electrode layer, the first bottom electrode layer, the second top electrode layer, and the second bottom electrode layer are independently selected from the group consisting of indium tin oxide, indium zinc oxide, aluminum tin oxide, aluminum zinc oxide, and indium germanium zinc oxide.

8. The solar cell module as claimed in claim 7, wherein the material of the first and second photoelectric conversion layers are independently selected from the group consisting of amorphous silicon, poly silicon, cadmium telluride, copper indium gallium selenium, gallium arsenide, and polymer; and
the material of the first and second P-N junction semiconductors are independently selected from the group consisting of amorphous silicon, poly silicon, cadmium telluride, copper indium gallium selenium, and gallium arsenide.

9. The solar cell module as claimed in claim 1, wherein the second photoelectric conversion layer comprises:
a third P-type semiconductor layer located on a side the same as the first surface of the second metal substrate;
a second I-type semiconductor layer located on the third P-type semiconductor layer; and
a third N-type semiconductor layer located on the second I-type semiconductor layer.

10. The solar cell module as claimed in claim 1, wherein the second P-N junction semiconductor comprises:
a fourth N-type semiconductor layer located on a side the same as the second surface of the second metal substrate; and
a fourth P-type semiconductor layer located on the fourth N-type semiconductor layer, and located between the fourth N-type semiconductor layer and the second bottom electrode layer.

11. The solar cell module as claimed in claim 1, wherein the first P-N junction semiconductor comprises:
a second N-type semiconductor layer located on a side the same as the second surface of the first metal substrate;
a first insulator located on a side the same as the second surface of the first metal substrate, and adjacent to the second N-type semiconductor layer; and
a second P-type semiconductor layer located on the first insulator, and located between the first insulator and the first bottom electrode layer.

12. The solar cell module as claimed in claim 1, wherein the second P-N junction semiconductor comprises:
a fourth N-type semiconductor layer located on a side the same as the second surface of the second metal substrate;
a second insulator located on a side the same as the second surface of the second metal substrate, and adjacent to the fourth N-type semiconductor layer; and
a fourth P-type semiconductor layer located on the second insulator, and located between the second insulator and the second bottom electrode layer.

13. The solar cell module as claimed claim 1, wherein the first photoelectric conversion layer is in ohmic contact with the first surface of the first metal substrate, and the first P-N junction semiconductor is in ohmic contact with the second surface of the first metal substrate; and
the second photoelectric conversion layer is in ohmic contact with the first surface of the second metal substrate, and the second P-N junction semiconductor is in ohmic contact with the second surface of the second metal substrate.

14. The solar cell module as claimed in claim 1, wherein the material of the first and second metal substrates is selected from the group consisting of gold, silver, copper, iron, tin, indium, aluminum, and platinum.

15. The solar cell module as claimed in claim 1, wherein the material of the first top electrode layer, the first bottom electrode layer, the second top electrode layer, and the second bottom electrode layer are independently selected from the group consisting of indium tin oxide, indium zinc oxide, aluminum tin oxide, aluminum zinc oxide, and indium germanium zinc oxide; and the material of the first and second photoelectric conversion layers are independently selected from the group consisting of amorphous silicon, poly silicon, cadmium telluride, copper indium gallium selenium, gallium arsenide, and polymer; the material of the first and second P-N junction semiconductors are independently selected from the group consisting of amorphous silicon, poly silicon, cadmium telluride, copper indium gallium selenium, and gallium arsenide.

16. The solar cell module as claimed in claim 1, wherein the first photoelectric conversion layer comprises:
a first N-type semiconductor layer located on the first surface of the first metal substrate;
a first I-type semiconductor layer located on the first P-type semiconductor layer; and
a first P-type semiconductor layer located on the first I-type semiconductor layer;
the first P-N junction semiconductor comprises:
a second P-type semiconductor layer located on a side the same as the second surface of the first metal substrate; and
a second N-type semiconductor layer located on the second N-type semiconductor layer, and located between the second N-type semiconductor layer and the first bottom electrode layer.

17. The solar cell module as claimed in claim 16, wherein the second photoelectric conversion layer comprises:
a third N-type semiconductor layer located on a side the same as the first surface of the second metal substrate;
a second I-type semiconductor layer located on the third P-type semiconductor layer; and
a third P-type semiconductor layer located on the second I-type semiconductor layer;
the second P-N junction semiconductor comprises:
a fourth P-type semiconductor layer located on a side the same as the second surface of the second metal substrate; and
a fourth N-type semiconductor layer located between the fourth N-type semiconductor layer and the second bottom electrode layer.

18. An electronic device including the solar cell module as claimed in claim 1, the electronic device comprising:
a display screen for displaying an image;
an input receiving unit for receiving an input instruction;
a control unit electrically coupled to the display screen and the input receiving unit for controlling the display screen to display the corresponding image in accordance with the input instruction received by the input receiving unit; and
the solar cell module as claimed in claim 1 electrically coupled to the display screen, the input receiving unit, and the control unit for providing power to the display screen, the input receiving unit, and the control unit.

19. A manufacturing method for solar cell comprising:
providing a first metal substrate having a first surface and a second surface opposite to the first surface;
depositing or coating a first P-type semiconductor layer on the first surface;
depositing or coating a first I-type semiconductor layer on the first P-type semiconductor layer;
depositing or coating a first N-type semiconductor layer on the first I-type semiconductor layer;
forming a first top electrode layer on the first N-type semiconductor layer;
depositing or coating a second N-type semiconductor layer on the second surface;
depositing or coating a second P-type semiconductor layer on the second N-type semiconductor layer; and
forming a first bottom electrode layer on the second P-type semiconductor layer.

20. A manufacturing method for solar cell comprising:
providing a first metal substrate having a first surface and a second surface opposite to the first surface;
depositing or coating a first N-type semiconductor layer on the first surface;
depositing or coating a first I-type semiconductor layer on the first N-type semiconductor layer;
depositing or coating a first P-type semiconductor layer on the first I-type semiconductor layer;
forming a first top electrode layer on the first P-type semiconductor layer;
depositing or coating a second P-type semiconductor layer on the second surface;
depositing or coating a second N-type semiconductor layer on the second P-type semiconductor layer; and
forming a first bottom electrode layer on the second N-type semiconductor layer.
